(19) United States
(12) Patent Application Publication
(10) Pub. No.: US 2011/0284721 A1
(43) Pub. Date: Nov. 24, 2011

(54) ORGANIC ELECTROLUMINESCENCE ILLUMINATION DEVICE

(75) Inventors: Akio Iwabuchi, Saitama (JP); Satoru Washiya, Saitama (JP)

(73) Assignee: SANKEN ELECTRIC CO., LTD., Saitama (JP)

(21) Appl. No.: 13/096,230

(22) Filed: Apr. 28, 2011

(30) Foreign Application Priority Data
May 21, 2010 (JP) 2010-116973

(51) Int. Cl. G01J 1/32; H01L 31/153

(52) U.S. Cl. 250/205; 257/80

(57) ABSTRACT

An organic electroluminescence illumination device including: an organic electroluminescence panel including: a transparent substrate; a transparent electrode formed on the transparent substrate; an organic light emitting layer formed on the transparent electrode; and a metal electrode formed on the organic light emitting layer, wherein the organic light emitting layer comprises: an illumination area that is formed as a main light emitting area of the organic electroluminescence illumination device; a reference area, which is electrically-insulated from the illumination area; and a light receiving area, which is electrically-insulated from the illumination area and the reference area; and an organic light emitting layer driving part that drives individually the illumination area and the reference area, wherein the organic light emitting layer driving part detects current flowing in the light receiving area.

### CROSS-REFERENCE TO RELATED APPLICATION

This application claims priority from Japanese Patent Application No. 2010-116973 filed on May 21, 2010, the entire subject matter of which is incorporated herein by reference.

### BACKGROUND

1. Technical Field

The present invention relates to an organic electroluminescence (EL) illumination device. More specifically, the present invention relates to an organic EL illumination device having an illuminance correction function.

2. Background Art

A related art discloses an organic EL illumination device in which an organic EL panel having a transparent substrate, a transparent electrode, an organic light emitting layer and a backside electrode, which are sequentially deposited thereon, is covered with a conductive housing except for a light emitting surface thereof. Further, the transparent electrode and the backside electrode are connected to a driving power supply, the transparent electrode is grounded, and thus housing radiation noise is reduced (for example, JP-A-2007-227523).

The illuminance of the organic EL illumination device is lowered as the organic EL panel is aging-deteriorated. Thus, the organic EL illumination device is required to have an illuminance correction function. A related art discloses an organic EL illumination device in which an organic EL panel has an opposite substrate, a transparent electrode, an organic light emitting layer, a backside electrode and a support substrate, which are deposited thereon, a light receiving device is formed in the opposite substrate or backside electrode, a temperature detection unit is formed in the organic light emitting layer, and thus the illuminance is corrected based on the detection outputs of the temperature detection unit (for example, JP-A-2008-185671).

### SUMMARY

However, according to the method of the related art, the light receiving device and the temperature detection unit are embedded in the organic EL panel, so that the organic EL panel is complicated. In addition, a control unit, which performs duty control to correct the illuminance, is required to have a memory and temperature detection unit, so that the configuration of the organic EL illumination device is further complicated and the cost is increased.

The present invention is made in consideration of the above. The present invention provides an organic EL illumination device having an illuminance correction function with a simple configuration.

With considering the above, an organic electroluminescence illumination device according to the present invention includes an organic electroluminescence panel and an organic light emitting layer driving part. The organic electroluminescence panel includes: a transparent substrate; a transparent electrode formed on the transparent substrate; an organic light emitting layer formed on the transparent electrode; and a metal electrode formed on the organic light emitting layer, wherein the organic light emitting layer comprises: an illumination area that is formed as a main light emitting area of the organic electroluminescence illumination device; a reference area, which is electrically-insulated from the illumination area; and a light receiving area, which is electrically-insulated from the illumination area and the reference area. The organic light emitting layer driving part drives the illumination area and the reference area, wherein the organic light emitting layer driving part detects current flowing in the light receiving area.

According to the organic EL illumination device of the present invention, it is possible to the organic EL illumination device having an illuminance correction function with a simple configuration.

### BRIEF DESCRIPTION OF THE DRAWINGS

FIG. 1A is a schematic view showing a sectional configuration of an organic EL illumination device, and FIG. 1B is a schematic view showing a plan configuration of an organic EL illumination device, according to a first illustrative aspect of the present invention.

FIG. 2 is a schematic view showing a sectional configuration of an organic EL illumination device according to a second illustrative aspect of the present invention.

FIG. 3 is a schematic view showing a sectional configuration of an organic EL illumination device according to a modified second illustrative aspect of the second illustrative aspect of the present invention.

### DESCRIPTION OF PREFERRED ILLUSTRATIVE ASPECTS

Hereinafter, an organic EL illumination device of illustrative aspects of the present invention will be described with reference to the drawings. In the drawings, the same or similar parts are indicated with the same or similar reference numerals. The drawings are schematic and are different from the actual device. In addition, the parts having different sizes or ratios in the drawings may be included.

### <First Illustrative Aspect>

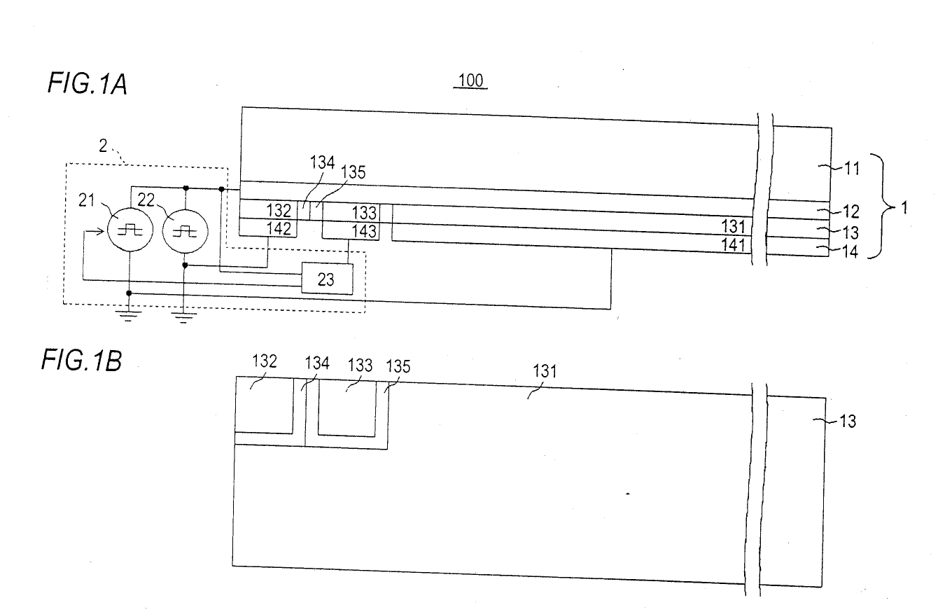

FIG. 1A is a schematic view showing a sectional configuration of an organic EL illumination device according to a first illustrative aspect of the present invention, and FIG. 1B shows a plan configuration thereof.

An organic EL illumination device 100 according to this illustrative aspect has an organic EL panel 1 that includes a transparent substrate 11, a transparent electrode (anode) 12, an organic light emitting layer 13 and a metal electrode (cathode) 14. The illumination device further has an illumination area 131, a reference area 132 and a light receiving area 133, which are formed in the organic light emitting layer 13, first and second insulation layers 134, 135 and an organic light emitting layer driving part 2.

The transparent substrate 11 is made of a support plate having transparency and electric insulation, such as a glass plate. The transparent electrode 12 is arranged on a side of the transparent substrate 11 opposite to a light emitting surface (upper surface in FIG. 1A) of the organic EL illumination device 100, made of a metal film having transparency and conductivity such as Indium Tin Oxide (ITO) or Zinc Oxide (ZnO) and functions as an anode electrode of the organic EL panel 1. The organic light emitting layer 13 is formed on the transparent electrode 12 and made from a low molecular material such as fluorescent or phosphorescence material, or a high molecular material. In addition, the organic light emitting layer 13 has such a structure that an electron injection layer, an electron transit layer, a light emitting layer, a hole transit layer and a hole injection layer are deposited from a side near to the transparent electrode 12. However, the layers are not shown for simplifying the explanation. The metal electrode 14 is formed on the organic light emitting layer 13 (hole injection layer), made of a metal film having reflectivity and conductivity such as Ag (silver) or Al (aluminum) and function as a cathode electrode of the organic EL panel 1. In addition, the metal electrode 14 has a first metal electrode 141 that is adjacent to the illumination area 131, a second metal electrode 142 that is adjacent to the reference area 132 and a third metal electrode 143 that is adjacent to the light receiving area 133. The first, second and third metal electrodes 141, 142, 143 are arranged to be independent each other.

The illumination area 131, the reference area 132 and the light receiving area 133 are provided in the organic light emitting layer 13 and are arranged with interposing the first and second insulation layers 134, 135. The illumination area 131 has a wider area than the reference area 132 and the light receiving area 133 in the organic light emitting layer 13, and functions as a main light emitting area of the organic EL illumination device 100. The reference area 132 is an area narrower than the illumination area 131 and emits light independently from the illumination area 131. The light receiving area 133 receives the light, which are emitted from the illumination area 131 and the reference area 132 and reflected in the transparent substrate 11 and the transparent electrode 12, and generates current in response to intensity of the emission light. Accordingly, the light receiving area 133 is adjacent to the illumination area 131 and the reference area 132 with interposing the first and second insulation layers 134, 135. The first insulation layer 134 is made of a material having electric insulation such as photoresist or polyimide and is arranged as a device separation area that separates the reference area 132 from the illumination area 131 and the light receiving area 133. The second insulation layer 135 made of the same material as the first insulation layer 134 and is arranged as a device separation area that separates the light receiving area 133 from the illumination area 131 and the reference area 132.

The organic light emitting layer driving part 2 has an illumination area driving part 21 that controls light emission of the illumination area 131, a reference area driving part 22 that controls light emission of the reference area 132 and a current detection part 23 that detect current flowing in the light receiving area 133.

The illumination area driving part 21 includes a well-known chopper circuit having a switching device controlled by PWM (Pulse Width Modulation), and includes a first power conversion unit that converts direct current power supply voltage and thus outputs desired constant current. The illumination area driving part 21 supplies the constant current by the first power conversion unit to the illumination area 131 via the transparent electrode 12 and the first metal electrode 141.

The reference area driving part 22 includes a well-known chopper circuit having a switching device controlled by the PWM and includes a second power conversion unit that converts direct current power supply voltage and thus outputs constant current. The reference area driving part 22 supplies the constant current by the second power conversion unit to the reference area 132 via the transparent electrode 12 and the second metal electrode 142.

The current detection part 23 has a current detection unit that detects current flowing in the light receiving area 133 and outputs a detection signal and an illuminance determination unit that determines illuminance of the illumination area 131, based on the detection signal, and outputs a determination signal. The current detection unit of the current detection part 23 is connected to the light receiving area 133 via the transparent electrode 12 and the third metal electrode 143. The illuminance determination unit is connected to the current detection unit and the illumination area driving part 21 and outputs the determination signal to the illumination area driving part 21.

The illumination area driving part 21 supplies the desired constant current to the illumination area 131 for a period during which the organic EL illumination device 100 is to be turn on, thereby enabling the illumination area 131 to emit the light with desired brightness. The constant current is current that is corrected to compensate for the aging deterioration of the organic light emitting layer 13. At this time, in response to the emission of light from the illumination area 131, current flows from the light receiving area 133 to the current detection unit of the current detection part 23. The current detection unit of the current detection part 23 outputs a first detection signal to the illuminance determination unit, in response to the current supplied from the illumination area 131. In addition, the reference area driving part 22 periodically supplies reference current for enabling the reference area 132 to emit light for a period during which the organic EL illumination device 100 is to be turned on. A supplying period of the reference current is longer than a supplying period for emitting the light. The reference current is current that is determined for enabling the reference area 132 to emit the light with desired brightness without considering the aging deterioration of the organic light emitting layer 13. At this time, in response to the emission of light from the reference area 132, current flows from the light receiving area 133 to the current detection unit of the current detection part 23. The current detection unit of the current detection part 23 outputs a second detection signal to the illuminance determination unit, in response to the current supplied from the light receiving area 133. The illuminance determination unit of the current detection part 23 compares the first electric signal and the second electric signal to detect a change of illuminance based on the aging deterioration of the organic light emitting layer 13 and outputs a determination signal to the illumination area driving part 21. The illumination area driving part 21 controls, based on the determination signal, a level of the constant current to be supplied to the illumination area 131. For example, when it is detected that the illuminance of the illumination area 131 is lowered, the constant current is leveled up or the operation of the illumination area driving part 21 is stopped.

According to the organic EL illumination device of this illustrative aspect, since the illumination area 131, the reference area 132 and the light receiving area 133 are formed in the organic light emitting layer 13, an external complicated illuminance detection apparatus is not necessary. In addition, since the illumination area 131 and the reference area 132 are formed in the single organic light emitting layer 13, a temperature detection unit and a temperature correction function for correctly detecting a change of illuminance are not necessary, even when the using environments such as surrounding temperature are changed. Further, since a characteristic variation between the illumination area 131 and the reference area 132 is little, it is possible to correctly detect the change of illuminance.

### <Second Illustrative Aspect>

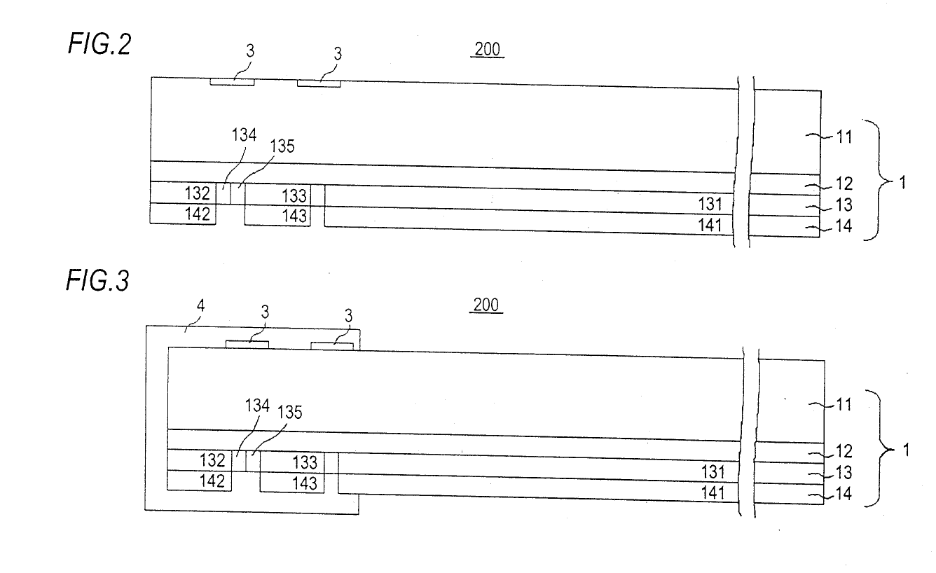

FIGS. 2 and 3 schematically show a sectional configuration of an organic EL illumination device according to a second illustrative aspect and a modified second illustrative aspect of the present invention. An organic EL illumination device 200 of these illustrative aspect also has the organic EL panel 1, the organic light emitting layer driving part 2 (not shown in FIGS. 2 and 3) and reflection areas 3.

The reflection areas 3 are formed on a side, which is a light emitting surface (upper surface in FIG. 2), of the transparent substrate 11 in the organic EL illumination device 200, and the reflection area 3 is provided at a area between the illumination area 131 and the light receiving area 133 and is provided at a area between the reference area 132 and the light receiving area 133. The reflection areas 3 are formed by performing a plating operation on the surface of the transparent substrate 11.

In addition, as shown in FIG. 3, the organic EL illumination device 200 may have a housing 4 that supports the illumination device 200, and the reflection areas 3 may be provided at a part of the housing 4. The housing 4 is called as a frame that keeps, protects and fixes the organic EL panel 1 and is made of metal or resin. The reflection areas 3 are formed by performing the plating operation on a surface of the housing 4 opposed to the transparent substrate 11.

According to the organic EL illumination device of this illustrative aspect, it is possible to achieve the same effects as the organic EL illumination device of the first illustrative aspect. In addition, since the emission of light from the illumination area 131 and the reference area 132 are incident into the light receiving area 133 via the reflection areas 3, it is possible to detect the change of illuminance more correctly.

Although the illustrative aspects of the present invention have been described, it should be noted that the present invention is not limited to the illustrative aspects. In other words, the illustrative aspects can be variously changed and modified within the scope of the present invention. For example, although the reference area 132 and the light receiving area 133 is formed at edge part of the organic light emitting layer 13 in the above-described illustrative aspects, the reference area 132 and the light receiving area 133 may be formed at an inside part of the organic light emitting layer 13, when seen from a plan view. In addition, the illumination area driving part 21 may control the level of the constant current, based on the detection signal of the current detection part 23. Further, the reflection areas 3 may be formed by performing a mirror surface processing or an asperity processing on the surface of the transparent substrate 11 or surface of the housing 4.

Additionally, although the first insulation layer 134 is adjacent to the second insulation layer 135 in the above-described illustrative aspects, the first insulation layer 134 and the second insulation layer 135 may be not adjacent to each other. Further, although the first and second insulation layer 134, 135 are provided as the device separation area, the first and second insulation layer 134, 135 may not be provided if it is possible that the reference area 132, the illumination area 131 and the light receiving area 133 is electrical-insulated with each other without providing the insulation layers. Further, although the light receiving area 133 is provided between the reference area 132 and the illumination area 131 in the above-described illustrative aspects, the reference area 132 may be provided between the light receiving area 133 and the illumination area 131.

What is claimed is:

1. An organic electroluminescence illumination device comprising:
an organic electroluminescence panel comprising:
a transparent substrate;
a transparent electrode formed on the transparent substrate;
an organic light emitting layer formed on the transparent electrode; and
a metal electrode formed on the organic light emitting layer, wherein the organic light emitting layer comprises:
an illumination area that is formed as a main light emitting area of the organic electroluminescence illumination device;
a reference area, which is electrically-insulated from the illumination area; and
a light receiving area, which is electrically-insulated from the illumination area and the reference area; and
an organic light emitting layer driving part that drives individually the illumination area and the reference area, wherein the organic light emitting layer driving part detects current flowing in the light receiving area.

2. The organic electroluminescence illumination device according to claim 1, further comprising:
a first insulation layer, which is interposed between the reference area and the illumination area; and
a second insulation layer, which is interposed between the light receiving area and the illumination area.

3. The organic electroluminescence illumination device according to claim 1,
wherein the light receiving area is arranged between the illumination area and the reference area.

4. The organic electroluminescence illumination device according to claim 1,
wherein the organic light emitting layer driving part corrects illuminance of the illumination area, based on the current flowing in the light receiving area.

5. The organic electroluminescence illumination device according to claim 1, further comprising:
a reflection area that is provided at an area between the illumination area and the light receiving area and is provided at an area between the reference area and the light receiving area, when seen from a plan view.

6. The organic electroluminescence illumination device according to claim 5,
wherein the reflection area is formed on the transparent substrate.

7. The organic electroluminescence illumination device according to claim 5,
wherein the reflection area is formed at a housing that covers the organic EL panel.

8. An organic electroluminescence panel comprising:
a transparent substrate;
a transparent electrode formed on the transparent substrate;
an organic light emitting layer formed on the transparent electrode; and
a metal electrode formed on the organic light emitting layer, wherein the organic light emitting layer comprises:
an illumination area that is formed as a main light emitting area;
a reference area, which is electrically-insulated from the illumination area; and
a light receiving area, which is electrically-insulated from the illumination area and the reference area.

9. An organic electroluminescence panel comprising according to claim 8, further comprising:
a reflection area is provided at a side of a light emitting surface of the transparent substrate.

10. A method of an illuminance correction of an organic electroluminescence illumination device, which comprises an organic light emitting layer including an illumination area, a reference area and a receiving area, the method comprising:
driving the illumination area by supplying constant current;
detecting first current supplied from the light receiving area in response to emission from the illumination area;
occasionally driving the reference area by supplying a reference current;
detecting second current supplied from the light receiving area in response to emission from the reference area;
comparing the first current and the second current; and
controlling the constant current, based on the comparing the first current and the second current.
